(19) United States
(12) Patent Application Publication
(10) Pub. No.: US 2002/0105014 A1
(43) Pub. Date: Aug. 8, 2002

(54) Body-tied-to-source with partial trench

(76) Inventor: Theodore W. Houston, Richardson, TX (US)

Correspondence Address: TEXAS INSTRUMENTS INCORPORATED, P O BOX 655474, M/S 3999, DALLAS, TX, 75265

(21) Appl. No.: 10/036,322

(22) Filed: Dec. 31, 2001

Related U.S. Application Data
(60) Provisional application No. 60/259,311, filed on Dec. 31, 2000.

(51) Int. Cl. H01L 31/072

(52) U.S. Cl. 257/200

(57) ABSTRACT

A silicon-on-insulator (SOI) MOS transistor including a semiconductive body upon an insulating layer on a semiconductor substrate, and a source region and drain region are adjacent to the semiconductive body with a gate positioned between the source and drain region and over the body. The source region includes a contact region of the same conductive type material as the semiconductive body, and a partial trench extends between the contact region and semiconductive body. The material underlying the partial trench conductively couples the semiconductive body and contact region whereby the semiconductive body and the source region are electircally connected.

### CROSS-REFERENCE TO RELATED APPLICATION

This application claims the benefit of U.S. Provisional Application Serial No. 60/(atty. Docket no. TI-31266P), filed Dec. 31, 2000 which is hereby incorporated by reference.

### BACKGROUND OF THE INVENTION

1. Field of the Invention

The present invention generally relates to semiconductors and integrated circuits. More particularly, the present invention relates to devices and methods to minimize floating body effects in a silicon-on-insulator (SOI) MOS transistor.

2. Description of the Related Art

Modern silicon-on-insulator (SOI) technology for integrated circuit (IC) fabrication involves the formation of transistors, either bipolar or FET, in certain regions or “mesas” within a layer of semiconductor material. The silicon mesas overlie a layer of an insulating material which generally overlies a silicon semiconductor substrate. In SOI technology, the silicon transistor mesas are generally isolated from the silicon substrate by an insulating layer of oxide.

In an SOI FET transistor, the body node or well underlying the transistor gate terminal is isolated from the bulk silicon substrate by the insulating layer, and consequently, the body of the transistor is electrically floating unless contacted by some means. In a partially-depleted MOS transistor, the voltage of a floating body is determined by capacitvie coupling and the balance of currents at the body to source and body to drain junctions. The result is that the floating body voltage varies in a way that depends on the previous switching history as well as the current state of the environment. The changes in body voltage result in a change in the threshold voltage of the transistor, sometimes with undesirable effects. For example, there will be increased uncertainty in switching delay, and possibly increased leakage current. The floating body node can permit parasitic bipolar effects in the FET devices, which can cause the device to be undesirably “latched” on, or add to leakage currents.

To counter the inherent problems associated with the floating body node of an SOI transistor, it is known to connect the body node to a fixed voltage. However, tying the body node to a fixed voltage degrades performance when the source voltage is raised above the fixed voltgae, as may occur in pass gate logic or in gate with stacked transistors. An alternative is to tie the body voltgae to the source terminal with a contact or tie. This eliminates some of the disadvantages of tying the body to a fixed voltage, and also eliminates the problems caused by a floating body voltage. Nevertheless, there are still disadvantages to tying the body voltage tot eh source voltage. The body contact takes space, either increasing the area or decreasing the effective width (drive current capacity) of the transistor.

Accordingly, it would be advantageous to provide an SOI MOS transistor that has minimal floating body effects in the partially depleted state, without using body contacts or ties that effect a significant area penalty. There is further benefit if this si done without tying the body to a fixed voltage. It is thus to the provision of such an improved SOI MOS transistor that the present invention is primarily directed.

### SUMMARY OF THE INVENTION

The present invention is a silicon-on-insulator (SOI) FET transistor that includes a semiconductor substrate with an insulating layer formed thereupon, with the components of the FET transistor formed upon the insulating layer. The semiconductive body of the transistor is of a first semiconductive type formed upon the insulating layer, a source region of a second semiconductive type is formed upon at least the insulating layer, a contact region is formed in the source region, the contact region of the first semiconductive type, and a drain region of a second semiconductive type is formed upon at least the insulating layer. The transistor includes a partial trench formed between the semiconductive body and the contact region, with the partial trench overlying a conductive material such that the semiconductive body and the source region are conductively connected.

If an n-channel transistor is fabricated, the semiconductive body is comprised of P type material, the source region is comprised of N type material, and the contact region is comprised of P type material. If a PMOS transistor is fabricated, the semiconductive body is comprised of N type material, the source region is comprised of P type material, and the contact region is comprised of N type material. The source region is conductively connected to the contact region, preferably by a silicide layer overlying both the source region and the contact region. Preferably, the contact region is remote from the channel region so as to not reduce the effective width of the transistor. Further, the conductive material underlying the partial trench is preferably N type material, although other conductive materials as known in the art of semiconductor fabrication can be alternately used.

The present invention further provides a method of fabricating an SOI FET transistor which includes the steps of forming an insulating layer upon a semiconductor substrate, forming a semiconductor layer on the insulating layer, and forming a plurality of isolation trenches in the semiconductor layer with at least one of the trenches, here referred to as a partial trench, not extending fully through the semiconductor layer. Then the method includes the steps of forming a merged body and source contact which ohmically contacts not only semiconductor material of a first conductivity type beneath the partial trench, but also a source region of a second conductivity type. Preferably this merged contact is laterally spaced away from the gate (to prevent channel length reduction), and the buried semiconductor material beneath the partial trench provides ohmic connection to the body. Preferably the partial trench shields the buried semiconductor material from the source/drain implant.

If the method is fabricating an NMOS transistor, the steps of forming a semiconductive body and a contact region comprised of a material of a first semiconductive type are forming a semiconductive body, partial trench region, and contact region comprised of P type material, and the steps of forming a source region and drain region comprised of a material of a second conductive type are forming a source region and drain region comprised of an N type material. If the method is fabricating a PMOS transistor, the steps of forming a semiconductive body, partial trench region, and contact region comprised of a material of a first semiconductive type are forming a semiconductive body comprised of N type material, and the steps of forming a source region and drain region comprised of a material of a second conductive type are forming a source region and drain region comprised of a P type material. And in one embodiment, the step of connecting the source region to the contact region is forming a silicide overlying both the source region and the contact region.

The present invention therefore provides a partial trench that ties the semiconductive body to the source region, which minimizes deleterious floating body effects.

Further, the present invention utilizes a contact region to make an n+/p-connection remotely from the gate so the connection does not adversely affect gate width nor length, nor increase gate capacitance.

### BRIEF DESCRIPTION OF THE DRAWINGS

FIG. 1 is a top view of an SOI MOS transistor illustrating the contact region within the source region, and a buried connection beneath a partial trench which ohmically connects the body to the source contact region.

FIGS. 2A and 2B are cross-sections of the SOI MOS transistor along lines 1-1 and 2-2 of FIG. 1.

FIGS. 3A-3D are a sequential set of drawings which illustrate a process sequence for fabrication of the described structures.

### DETAILED DESCRIPTION OF THE INVENTION

With reference to the figures in which like numerals represent like elements throughout, FIG. 1 is a top view of an SOI MOS transistor 10 with a source region 12 and a drain region 14, both adjacent semiconductive body 16. (The lateral boundary between body 16 and the source and drain regions will approximately correspond to the edge of the gate stripe, which is not shown here for clarity.)

The illustrated transistor 10 is an NMOS transistor, and accordingly, the semiconductive body 16 in this example is P type material, while the source region 12 and the drain region 14 are N type. The invention includes a contact region 20 formed in the source region 12, remotely from the gate 32.

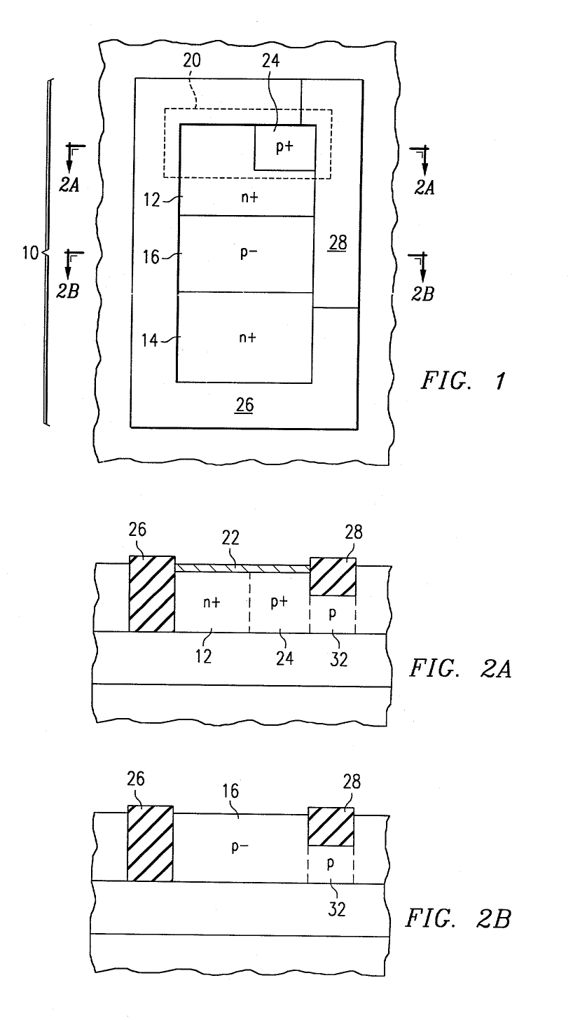

As seen in the sectional view of FIG. 2A (taken along line 1-1 of FIG. 1), silicide cladding 22 has been formed on all exposed semiconductor material within the source contact window 20. This silicide cladding makes ohmic contact both to source diffusion 12, and also to a p+ body contact diffusion 24 which has been patterned within the area of the source 12, remote from the gate. (The p+ body contact diffusion can be formed, for example, by modifying the n+ and p+ implant masks, so that this part of the NMOS source area is shielded from the n+ source/drain implant but exposed to the p+ source/drain implant.)

The p+ body contact diffusion 24 is located at an edge of the source area, adjacent to a partial trench 28. The p-type semiconductor material 32 beneath the partial trench 28 provides a junctionless connection from p+ diffusion 24 to body 16.

Full trenches 26, also filled with oxide, provide lateral isolation in all other locations, at least where buried interconnect is not desired.

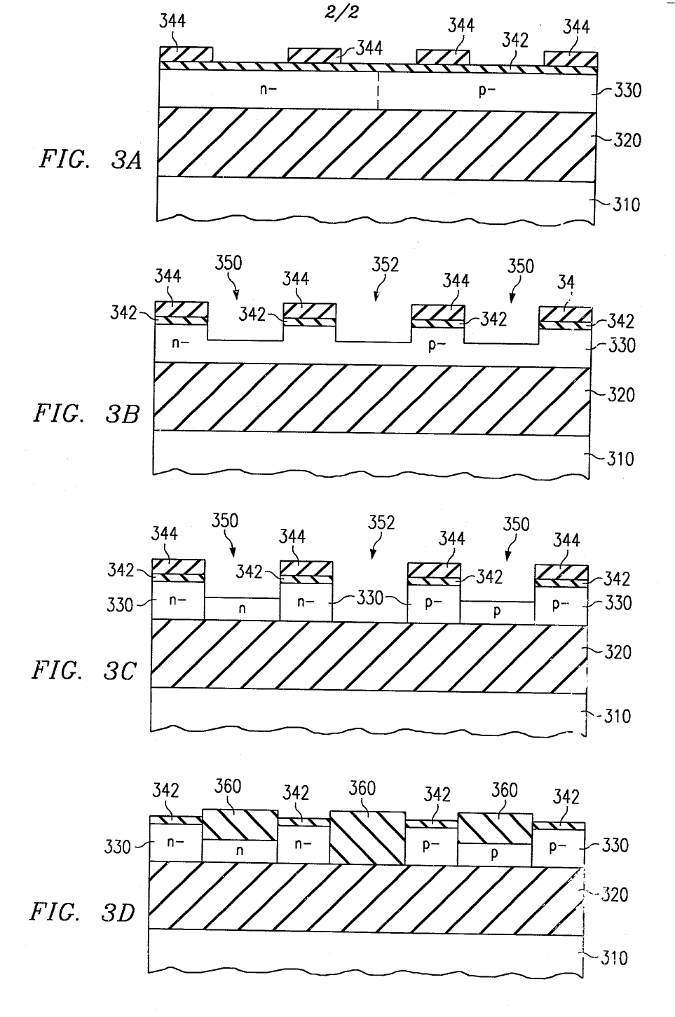

FIGS. 3A-3D are a sequential set of drawings which illustrate a process sequence for fabrication of the described structures. In a sample embodiment, the process sequence can include the steps of:

start with silicon layer 330 on insulator 320 (on substrate 310)

form pad oxide 342

do channel implants

deposit, pattern and etch the nitride 344 for active pattern

This produces the structure of FIG. 3A.

(Optional) implant into the isolation region. This is to increase the doping in what will be the partial trench. This requires a pattern step if both n and p are implanted, but not if the partial trench is used only for one type (n-channel or p-channel)

Partially etch the trench.

This produces the structure of FIG. 3B.

(Optional) implant into the isolation region..

Deposit resist and pattern to cover partial trench region.

Complete trench etch.

This produces the structure of FIG. 3C.

Fill trench with a dielectric 360, planarize, and remove nitride.

This produces the structure of FIG. 3D.

The partial trench 22 is formed, preferably by etching, extending from the contact region 20 to the semiconductive body 16, and then the conductive material is placed in the partial trench 22, such that the semiconductive body 16 and the source region 20 at least partially electrically float together. A gate 42 is then placed on the semiconductive body 16 and between the source region 12 and drain region 14 thereby creating the MOS transistor. In such embodiment, the conductive material can be placed in the partial trench 22, and then a damascene process can be used to clear the excess conductive material prior to the field oxide region 36 being formed on the source region 12, contact region 20, drain region 14, and semiconductive body 16.

While there has been shown a preferred and alternate embodiment of the present invention, it is to be understood that certain changes may be made in the forms and arrangement of the elements and steps of the method without departing from the underlying spirit and scope of the invention as is set forth in the claims. Many additional structure and process details can be implemented if desired, in combination with the broadly novel teachings given above.

What is claimed is:

1. An SOI transistor, comprising:
an insulating layer;
a semiconductive body of a first semiconductive type formed upon the insulating layer; a source region of a second semiconductive type formed upon at least the insulating layer;
a contact region electrically connected to the source region;
a drain region of a second semiconductive type formed upon at least the insulating layer;
a partial trench formed adjacent to the semiconductive body and adjacent to the contact region, the partial trench overlying conductive material, wherein the semiconductive body and the source region are electrically connected.

2. The transistor of claim 1, wherein the semiconductive body is comprised of P type material, the source region is comprised of N type material, and the contact region is comprised of P type material.

3. The transistor of claim 1, wherein the semiconductive body is comprised of N type material, the source region is comprised of P type material, and the contact region is comprised of N type material.

4. The transistor of claim 1, wherein the conductive material underlying the partial trench is semiconductor material of the first semiconductive type.

5. A method of fabricating an SOI field-effect transistor, comprising the steps of:
forming a plurality of dielectric-filled trenches into a first-conductivity-type semiconductor layer which overlies an insulating layer, at least one of the trenches being a partial trench which does not extend down to said insulating layer, and others of said trenches being full trenches which extend down to said insulating layer;
forming a patterned gate over said semiconductor layer;
forming second-conductivity-type source and drain diffusions in exposed portions of said semiconductor layer, and also forming at least one first-conductivity-type body contact diffusion abutting a respective one of said source diffusions and at least one of said partial trenches; and
ohmically contacting said body contact diffusion and said respective source diffusion;
whereby said body contact diffusion, in combination with remaining first-conductivity-type material beneath said partial trench, provides ohmic connection between said respective source diffusion and remaining first-conductivity-type material beneath said gate adjacent to said respective source.

6. The method of claim 5, wherein said ohmically contacting step comprises formation of a metallic surface coating.

7. A semiconductor-on-insulator transistor structure, comprising:
first and second source/drain regions of a first conductivity type, separated by a conductivity-modulated body region of a second conductivity type;
a body extension of said second conductivity type, which extends from said body beneath an insulating partial trench; and
a metallic contact
which is positioned over one of said source/drain regions at a location which is laterally spaced from said body region, and
which is ohmically connected both to said one source/drain region and also to said body extension.
